(19) United States
(12) Patent Application Publication
(10) Pub. No.: US 2007/0218677 A1
(43) Pub. Date: Sep. 20, 2007

(54) Method of Forming Self-Aligned Air-Gaps Using Self-Aligned Capping Layer over Interconnect Lines

(76) Inventors: Manfred Engelhardt, Feldkirchen-Westerham (DE); Andreas Stich, Gruenwald (DE); Eugen Unger, Augsburg (DE)

Correspondence Address: BAKER BOTTS, L.L.P., 98 SAN JACINTO BLVD., SUITE 1500, AUSTIN, TX, 78701-4039, US

(21) Appl. No.: 11/276,801

(22) Filed: Mar. 15, 2006

(51) Int. Cl. H01L 21/4763

(52) U.S. Cl. 438/618

(57) ABSTRACT

A method for forming self-aligned air-gaps as IMD wherein the interconnect lines are covered with self-aligned capping layer and wherein the process of forming the capping layer is a maskless process is provided.

### TECHNICAL FIELD

The invention relates to a method for the formation of self-aligned air-gaps between interconnect lines wherein interconnects lines are covered with self-aligned capping layers.

### BACKGROUND

It is known from the literature that by scaling down the IC technology, the interconnect capacitance can limit performance. In fact the interconnect capacitance can lead to RC delay of interconnects and thereby limit the device speed. Furthermore, it could raise the power consumption of a device and therefore its performance.

To overcome this limiting factor, during the manufacturing of devices for semiconductor technology, dielectric materials like low k materials and air-gaps were introduced in the interconnect process, as IMD (Inter Metal Dielectric), to reduce the capacitance between interconnect lines and thereby to increase the performance of the devices.

As a further limiting factor with the scaling down of interconnects, the interlayer between dielectric material and metal interconnect line, plays a crucial role on the performance of a device during the fabrication process of IMD-interconnect. Conventionally known as diffusion barrier of metal, it ensures the dielectric adhesion to the metal interconnect and improves IMD reliability. In addition, as a capping layer it should ensure the electrical performance of the metal by protecting the metal interconnect from oxidation during the process of forming air-gaps as IMD.

However, although methods are known to form air-gaps, manufacturing processes are difficult and expensive to implement.

### SUMMARY

According to one embodiment, a method for forming self-aligned air-gaps as IMD wherein interconnect lines are covered with self-aligned capping layer and wherein the process of forming the capping layer is a maskless process is provided. As a result devices with high performance, scaled down interconnects and reduced cost can be manufactured.

The method allows for the selective deposition of the capping layer over the interconnect lines without the use of a mask or lithography. As a result the production costs of the manufacturing process is reduced. Further, the size of the interconnect and the distance between interconnect lines can be reduced without increasing the manufacturing costs, since the processing steps do not change

### BRIEF DESCRIPTION OF THE DRAWINGS

Various aspects and advantages of the present invention will be apparent from the following detailed description of the invention and the accompanying drawings wherein:

FIG. 1 shows an embodiment having a substrate, an etch-stop layer and a dielectric layer, in which gaps are created by means of etching;

FIG. 2 shows the system of FIG. 1 wherein barrier layer is deposited on the bottom and side walls of the gap;

FIG. 3 shows another embodiment, wherein the gaps are filled with a metal layer;

FIG. 4a shows the system of FIG. 3 wherein, according to one embodiment, the top surface of metal layer is planarized to the top surface of barrier layer;

FIG. 4b shows the system of FIG. 4a wherein, for an embodiment, the top surface of said system is planarized to the top surface of dielectric layer;

FIG. 5 shows schematically the system of FIG. 4b wherein, according to one embodiment, a self-aligned capping layer is deposited selectively on top of the filled gaps said interconnect lines;

FIG. 6 shows, for an embodiment, the system of FIG. 5 wherein between the interconnect lines the dielectric layer is etched selectively to the capping layer; and

FIG. 7 shows the system of FIG. 6 wherein, according to one embodiment, a second dielectric layer is deposited in a non-conform way to create an air-gap between the interconnect lines.

The drawings 1 to 7 are not necessarily to scale. They represent schematically the method for the formation of self-aligned air-gaps as IMD wherein interconnect lines are covered with self-aligned capping layer according to the embodiments.

### DETAILED DESCRIPTION

While specific exemplary embodiments of the invention will now be described in detail for illustrative purposes, it should be understood that the present invention is not limited to the specific embodiments described in the specification. A person skilled in the art can recognize that many widely different embodiments of the present invention may be constructed in a variety of other applications without departing from the spirit and scope of the present invention. Further, it would be apparent to a person skilled in the pertinent art that all values discussed herein are exemplary, as values can vary depending on an application or specification of an application.

According to an embodiment, a method of forming air-gaps between interconnect lines wherein the interconnect lines are covered with a self-aligned capping barrier, may include the following:

A dielectric layer is deposited over a substrate. The substrate may be a semiconductor device, e.g., but is not limited to a memory or a logic device. For example, in between the interconnect levels, the top surface of the substrate may consist of an inter-level dielectric layer of subjacent interconnect layers. It must be understood that a semiconductor device is underneath this inter-level dielectric layer, including one or more interconnect levels.

According to one embodiment, the first dielectric layer may be but is not limited to a low k material. According to another embodiment present invention the first dielectric layer may be but is not limited to SiO₂ or SiOF.

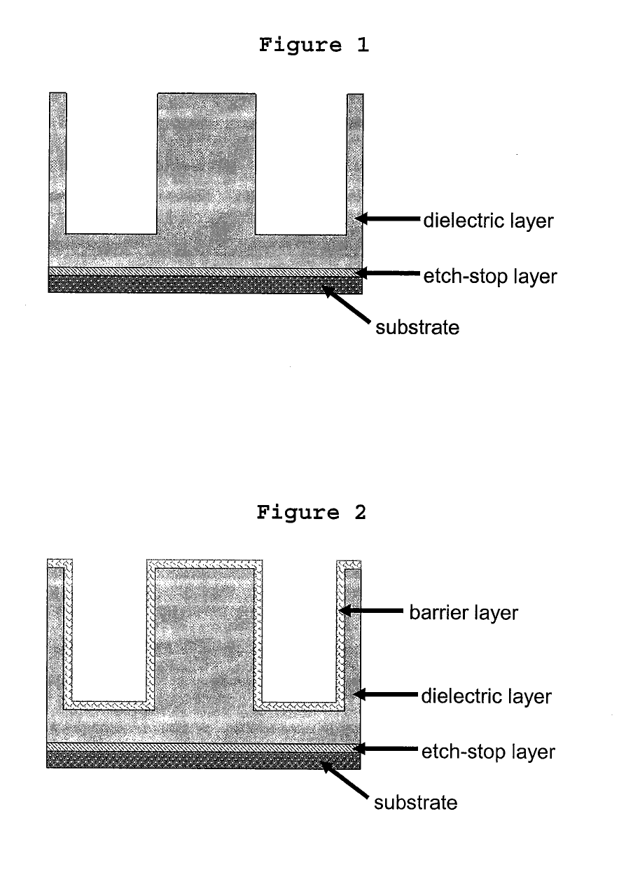

As illustrated on FIG. 1, according to another embodiment, an etch-stop layer may be deposited on the surface of the substrate before the deposition of the first dielectric layer. This etch-stop layer is deposited over the substrate to control the depth of the air-gap trenches in a subsequent fabrication step.

According to an embodiment, the etch-stop layer may be but is not limited to a dielectric material which has a different etch selectivity than the first dielectric layer. According to another embodiment the etch-stop layer may be but is not limited to Si₃N₄ or SiC.

According to another embodiment, the procedure may further include an etch process of the first dielectric layer to form gaps inside of the dielectric layer as shown on FIG. 1. The procedure of gap formation in the dielectric layer may include a wet-chemical etch based on a HF solution or a dry etch process but is not limited to a plasma etch process like CF₄, CHF₃ or C₄F₈.

As shown on FIG. 2, after the formation of the gaps in the dielectric layer, according to an embodiment, a barrier layer will be deposited over the dielectric layer and inside of the gaps. This barrier layer could be for example Ta or TaN or a combination thereof. Further, according to another embodiment, the barrier layer may be but is not limited to Ti or TiN or a combination thereof.

The deposition process may be performed by Chemical Vapour Deposition (CVD) or Physical Vapour Deposition (PVD) or Atomic Layer Deposition (ALD) process. The conformity of the surface/wall deposition of the barrier layer could vary from 1:1 to 2:1 depending on the technique and the process conditions such as, but not limited to gas pressure or gas flow rate or Radio Frequency (RF) bias or bias voltage.

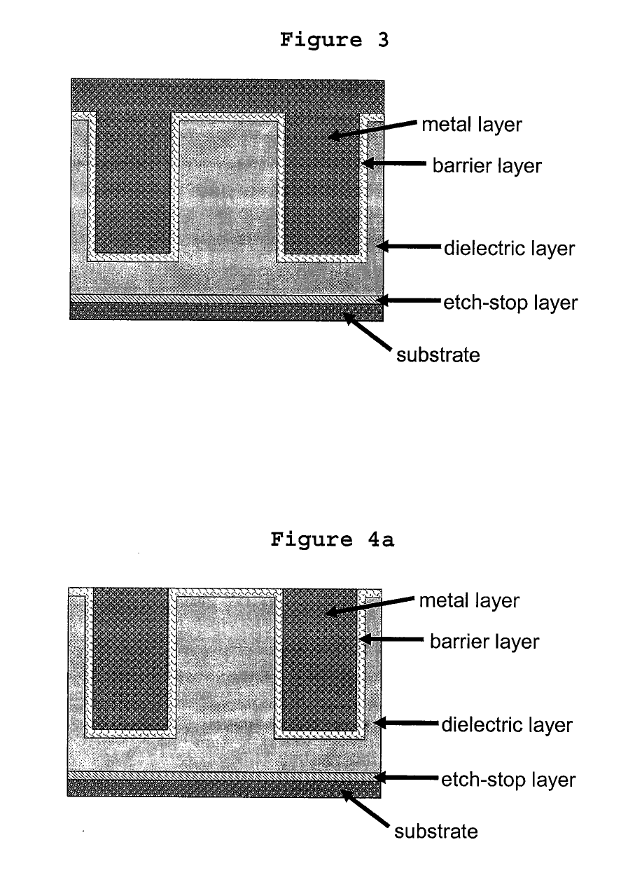

Referring to FIG. 3, a metal layer is deposited over the barrier layer and fills the gaps to form the interconnect lines. According to an embodiment, the metal layer may be Cu or W or Silver.

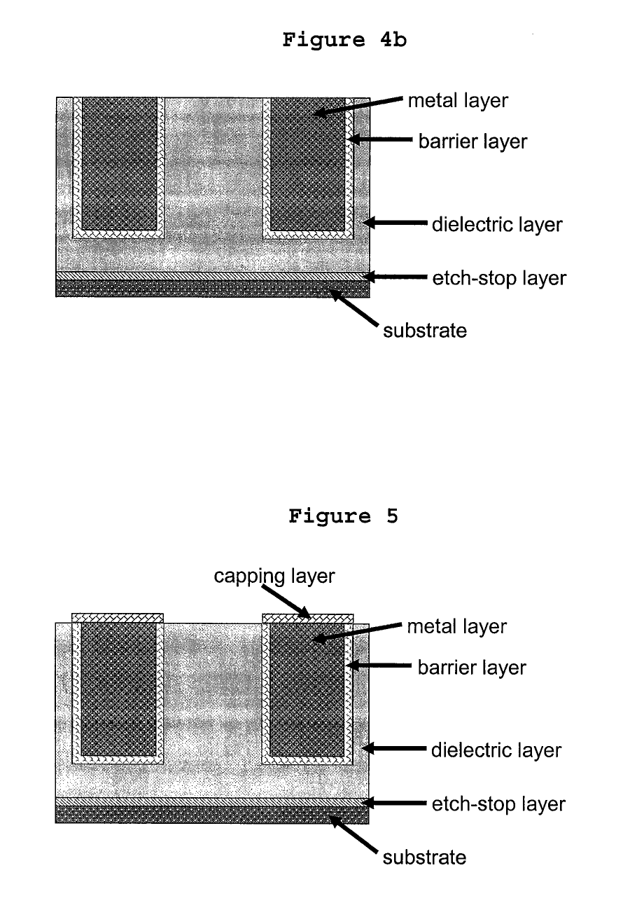

According to an embodiment, the top surface of the gap is planarized in few steps as shown respectively on FIGS. 4a and 4b. For both steps, the planarization may be performed by a Chemical Mechanical Polishing (CMP) process. In a first step, the top surface of the metal layer is planarized to the surface of the barrier layer as shown in FIG. 4a. In the second step of polishing, as illustrated on FIG. 4b, the top surface of the interconnect lines is planarized to the surface of the dielectric layer.

According to another embodiment, the procedure may further include the deposition of a self-aligned capping layer over the interconnect lines. The deposition procedure is a maskless, and is a lithography independent process, that may be obtained by a wet-chemical process. The system as shown for example in FIG. 4b is submerged in a solution which is heated up to a desired temperature. The temperature can vary from, e.g., about 70° C. to, e.g., about 90° C.

According to another embodiment, the capping layer is deposited selectively over the interconnect line. The ratio of deposition selectivity of capping layer over interconnect line to the deposition selectivity of capping layer over dielectric layer may depend on the cleaning conditions of the surface of the system and has at least a value of about 100/1.

Further the capping layer should resist oxidation during the etch process of the first dielectric layer and the deposition process of the non-conformal second dielectric layer. According to one embodiment, this selectively grown capping layer may be selected from a group of materials consisting of Ni or Co or Re or W or Mb or P or B and combinations thereof, e.g., but not limited to COWP or NiMoP or NiReP.

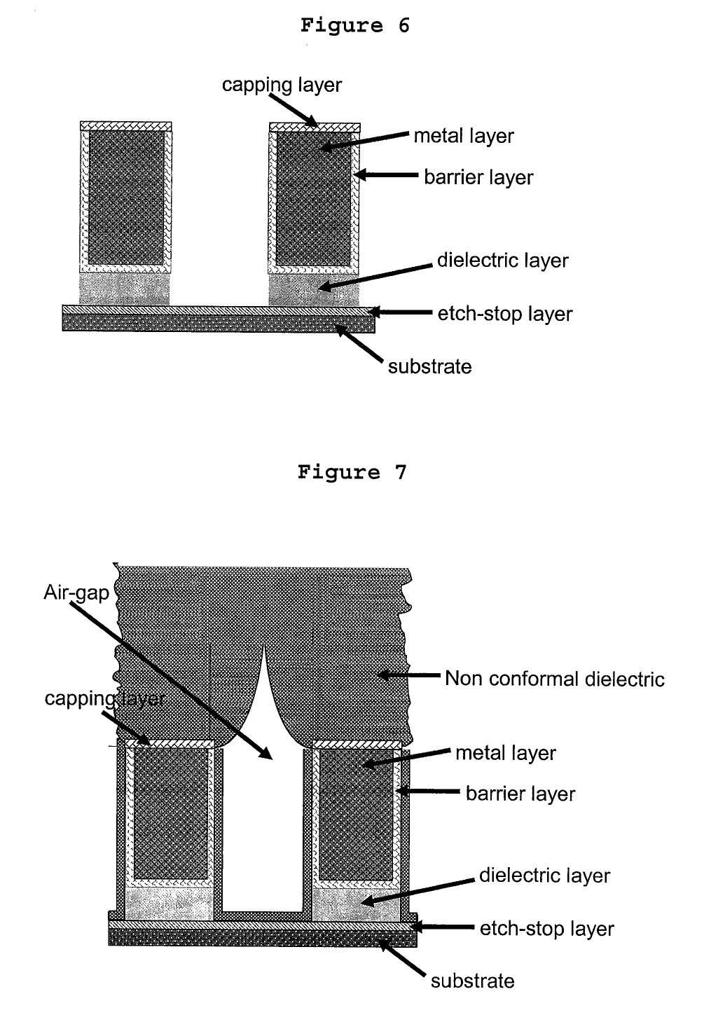

According to another embodiment, the procedure may further include an etch process of the first dielectric layer disposed between interconnect lines as shown, e.g., on FIG. 6. The etching of first dielectric layer, selective to the capping layer, may be performed by a wet-chemical etch based on a HF solution or a dry etch process or a combination thereof. The dry etch may be but is not limited to a plasma etch process like CF₄, CHF₃ or C₄F₈.

According to an embodiment, the procedure may as further step include deposition of a second dielectric layer between interconnect lines. The deposition process of the IMD may be performed by a non-conformal procedure which may lead to the formation of air-gaps between interconnect lines as shown on FIG. 7.

According to an embodiment, the deposition of IMD and the formation of air-gaps may be obtained by means of a dry deposition process but is not limited to CVD plasmas like Silane and oxygen.

Further, the non-conformal second dielectric layer may be a low k material. According to another embodiment, the non-conformal second dielectric layer may be SiO₂.

The non-conformal deposition conditions of the IMD layer and the formation of air-gaps may depend on the geometric factors such as the height and the distance of interconnect lines and the process conditions, such as pressure or gas flow rate or temperature. Based on the process conditions, according to one embodiment, a surface to side-wall coverage of IMD may be obtained between, e.g., about 5/1 to, e.g., a ratio of about 20/1.

We claim:

1. A method of fabricating self-aligned air-gaps between interconnect lines comprising:
depositing a first dielectric layer on a substrate,
etching said dielectric layer to form gaps,
depositing a barrier layer in said gaps,
depositing a metal layer over said barrier layer to fill said gaps and form said interconnect lines,
planarizing the surface of said gaps,
depositing selectively a capping layer over said metal layer,
etching said dielectric layer between said interconnect lines,
depositing a second dielectric layer between said interconnect lines to form said air-gaps.

2. A method according to claim 1, wherein an etch-stop layer is deposited on said substrate before depositing said first dielectric layer.

3. A method according to claim 2, wherein said etch-stop layer has a different etch selectivity than said first dielectric layer.

4. A method according to claim 3, wherein said etch-stop layer is a dielectric material.

5. A method according to claim 3, wherein said etch-stop layer is selected from the group of Si₃N₄ and SiC.

6. A method according to claim 1, wherein said substrate is a semiconductor device.

7. A method according to claim 6, wherein said semiconductor device is one of a memory device and a logic device.

8. A method according to claim 1, wherein said first dielectric layer is a low k material.

9. A method according to claim 8, wherein said first dielectric layer is selected from the group of Silicon-oxide and SiOF.

10. A method according to claim 1, wherein said barrier layer is one of Ta and TaN and combination of Ta and TaN.

11. A method according to claim 1, wherein said barrier layer is one of Ti and TiN and combination of Ti and TiN.

12. A method according to claim 1, wherein said metal layer is one of Cu, W and Ag.

13. A method according to claim 1, wherein said capping layer is one of Ni, Co, Re, W, Mb, P, B and combinations of Ni, Co, Re, W, Mb, P and B.

14. A method according to claim 1, wherein the deposition selectivity of said capping layer on said interconnect line is at least 100/1.

15. A method according to claim 1, wherein said capping layer is formed by means of wet-chemical deposition.

16. A method according to claim 15, wherein the deposition temperature of said capping layer is approximately in the range of 70° C. to 90° C.

17. A method according to claim 1, wherein said second dielectric layer is a non-conformal dielectric material.

18. A method according to claim 17, wherein said second dielectric layer is a low k material.

19. A method according to claim 17, wherein said second dielectric layer is Silicon-oxide.

20. A method according to claim 1, wherein surface to side-wall coverage of said second dielectric layer is approximately in the range of 5/1 to 20/1.
